(19) United States
(12) Patent Application Publication
(10) Pub. No.: US 2012/0112193 A1
(43) Pub. Date: May 10, 2012

(54) TRANSISTOR ARRAY SUBSTRATE

(75) Inventors: WEI-YEN CHIU, Taoyuan County (TW); CHIN-HAI HUANG, Taoyuan County (TW)

(73) Assignee: CHUNGHWA PICTURE TUBES, LTD., Taoyuan (TW)

(21) Appl. No.: 13/088,808

(22) Filed: Apr. 18, 2011

(30) Foreign Application Priority Data
Nov. 10, 2010 (TW) 099138663

(51) Int. Cl. H01L 33/08

(52) U.S. Cl. 257/59; 257/71; 257/E33.053

(57) ABSTRACT

A transistor array substrate includes a substrate, a plurality of scan lines, a plurality of data lines, and a plurality of pixel units. The scan lines, the data lines, and the pixel units are all disposed on the substrate. Each pixel unit includes a first transistor, a second transistor, a first pixel electrode, a second pixel electrode, a first storage capacitor, and a second storage capacitor. The second transistor and the first transistor are electrically connected with the same scan line and the same data line. The second transistor and the first transistor are connected in series. The first pixel electrode is electrically connected with the first transistor, and the second pixel electrode is electrically connected with the second transistor. The first storage capacitor is electrically connected with the first transistor and the second transistor, and the second storage capacitor is electrically connected with the second transistor.

### CROSS-REFERENCE TO RELATED APPLICATION

This application claims the benefit of Taiwan Patent Application No. 099138663, filed on Nov. 10, 2010, which is hereby incorporated by reference for all purposes as if fully set forth herein.

### BACKGROUND OF THE INVENTION

1. Field of Invention

The present invention relates to an active component array substrate, and particularly to a transistor array substrate.

2. Related Art

In current wide viewing angle liquid crystal display (LCD) technologies, it is an important task to solve the color shift problem. Specifically, the so-called color shift refers to a situation that a color of a picture of a liquid crystal display varies with the change of a viewing angle, so that the display picture turns a little white when the viewing angle is increased. In order to solve this color shift problem, two methods are proposed currently.

One method is that one more coupling capacitor is fabricated in a single pixel unit. The coupling capacitor utilizes the voltage coupling effect, so that a pixel electrode in the single pixel unit can provide different electric fields. Thus, the liquid crystal molecules are arranged differently so that the pixel units display different gray levels, so as to improve the color shift problem. However, the coupling capacitors may be influenced easily when manufacturing process parameters are changed, so that the electric fields of the pixel electrodes cannot be precisely controlled, thereby causing a negative influence on the picture quality of the liquid crystal display.

The other method is that an additional transistor is added in a single pixel unit, that is, two transistors exist in the single pixel unit. Through the two transistors, the pixel electrode in the single pixel unit provides different electric fields, so as to achieve the efficacy of improving the color shift. However, this method requires to fabricate a large number of scan lines, and signals with independent waveforms must be input to each scan line, so the fabrication procedure is very complex, and the method must use customized driver integrated circuits (driver ICs), thus greatly increasing the fabrication cost.

### SUMMARY OF THE INVENTION

The present invention provides a transistor array substrate, so as to solve the color shift problem, thereby promoting the display quality of the liquid crystal display.

In order to achieve the purpose, the present invention provides a transistor array substrate including a substrate, a plurality of scan lines, a plurality of data lines, and a plurality of pixel units. The scan lines, the data lines, and the pixel units are all disposed on the substrate. Each pixel unit includes a first transistor, a second transistor, a first pixel electrode, a second pixel electrode, a first storage capacitor, and a second storage capacitor. The second transistor and the first transistor are electrically connected with the same scan line and the same data line, and the second transistor and the first transistor are connected in series. The first pixel electrode is electrically connected with the first transistor, and the second pixel electrode is electrically connected with the second transistor. The first storage capacitor is electrically connected with the first transistor and the second transistor, and the second storage capacitor is electrically connected with the second transistor.

Based on the foregoing, through the first transistor and the second transistor in each pixel unit, the present invention can utilize a voltage division rule of capacitors and enable liquid crystal capacitors corresponding to the first pixel electrode and the second pixel electrode respectively to generate different feed-through voltages, thereby achieving the efficacy of eliminating the color shift.

In order to make the aforementioned features and advantages of the present invention more comprehensible, embodiments of the present invention are illustrated in detail hereinafter with reference to the accompanying drawings.

### BRIEF DESCRIPTION OF THE DRAWINGS

The present invention will become more fully understood from the detailed description given herein below for illustration only, and thus are not limitative of the present invention, and wherein:

FIG. 1A is a schematic top view of a transistor array substrate according to a first embodiment of the present invention;

FIG. 1B is a schematic circuit diagram of a liquid crystal display panel with the transistor array substrate in FIG. 1A;

FIG. 2 is a schematic top view of a transistor array substrate according to a second embodiment of the present invention;

FIG. 3 is a schematic top view of a transistor array substrate according to a third embodiment of the present invention; and

FIG. 4 is a schematic top view of a transistor array substrate according to a fourth embodiment of the present invention.

### DETAILED DESCRIPTION OF THE INVENTION

The implementation of the present invention mainly is that two pixel electrodes are designed in a single pixel unit and enable liquid crystal capacitors corresponding to both of the pixel electrodes respectively to generate different feed-through voltages by utilizing a voltage division rule of capacitors, thereby eliminating the color shift. Specifically, the pixel electrodes firstly receive a source input signal, so as to charge the liquid crystal capacitors. Then, output of the source input signal is paused, so as to enable the liquid crystal capacitors to start discharging. At this time, a voltage of the pixel electrodes firstly drops suddenly and then drops slowly. A voltage difference in the sudden drop period is referred to as a feed-through voltage.

Then, after the output of the source input signal is stopped, and the voltage of the pixel electrodes drops suddenly, at this time, these pixel electrodes provide a pixel voltage for changing the arrangement of liquid crystal molecules. The pixel voltage basically approximates a voltage obtained after the feed-through voltage is subtracted from the voltage of the source input signal. Because feed-through voltages generated by these liquid crystal capacitors are different, the pixel electrodes in the same pixel unit generate different pixel voltages respectively, so that a single pixel unit can display two different gray levels, thereby solving the color shift problem.

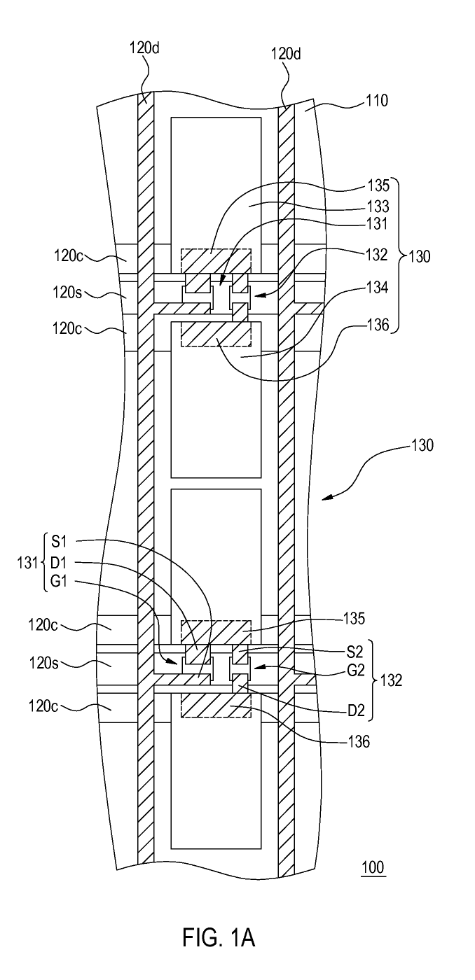

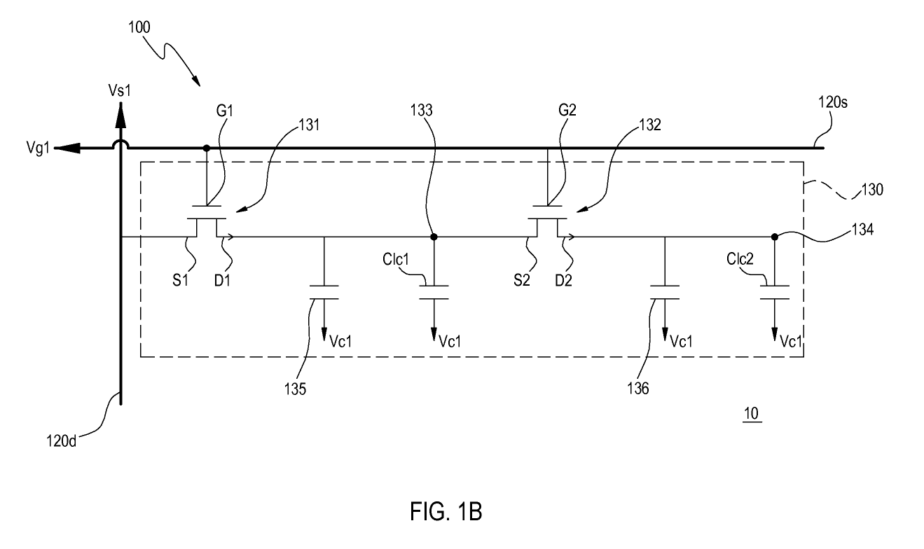

Specifically, FIG. 1A is a schematic top view of a transistor array substrate according to a first embodiment of the present invention. Referring to FIG. 1A, a transistor array substrate 100 of the first embodiment can be assembled with a color filter substrate (not shown), and a liquid crystal material is filled between the transistor array substrate 100 and the color filter substrate, so as to form a liquid crystal display panel (LCD panel, not shown). The transistor array substrate 100 includes a substrate 110, a plurality of scan lines 120s, a plurality of data lines 120d, a plurality of common lines 120c, and a plurality of pixel units 130.

The scan lines 120s, data lines 120d, common lines 120c, and pixel units 130 are all disposed on a substrate 110, and each pixel unit 130 includes a first transistor 131, a second transistor 132, a first pixel electrode 133, a second pixel electrode 134, a first storage capacitor 135, and a second storage capacitor 136. The first pixel electrode 133 and the second pixel electrode 134 in each pixel unit 130 are arranged into one row along the data line 120d, as shown in FIG. 1A.

The first transistor 131 and the second transistor 132 in the same pixel unit 130 are electrically connected with the same scan line 120s and the same data line 120d. Specifically, the first transistors 131 and second transistors 132 are all field-effect transistors (FET), so each first transistor 131 includes a first gate G1, a first source S1, and a first drain D1, and each second transistor 132 includes a second gate G2, a second source S2, and a second drain D2.

FIG. 1B is a schematic circuit diagram of a liquid crystal display panel with the transistor array substrate in FIG. 1A. Referring to FIG. 1A and FIG. 1B, a liquid crystal display panel 10 includes the transistor array substrate 100, while a scan line 120s is electrically connected with a gate power source Vg1 and transmits a gate input signal provided by the gate power source Vg1. The gate power source Vg1, for example, is a gate driving integrated circuit. In each pixel unit 130, the first gate G1 and the second gate G2 are electrically connected with the same scan line 120s, so the first transistor 131 and the second transistor 132 use the same gate input signal. Therefore, the first transistor 131 and the second transistor 132 in the same pixel unit 130 basically can be switched on or off by one scan line 120s simultaneously.

The data line 120d is electrically connected with a source power source Vs1 and transmits a source input signal provided by the source power source Vs1. The source power source Vs1, for example, is a source driving integrated circuit (Source IC). In each first transistor 131, the first source S1 is electrically connected with the data line 120d, and the first drain D1 is electrically connected with the second source S2, so the first transistor 131 and the second transistor 132 are connected in series. Therefore, the first transistor 131 and the second transistor 132 in the each pixel unit 130 use the same source input signal.

Furthermore, the first drain D1 is further electrically connected with the first storage capacitor 135 and the first pixel electrode 133, and the second drain D2 is further electrically connected with the second storage capacitor 136 and the second pixel electrode 134, so the first pixel electrode 133 and the first storage capacitor 135 are electrically connected with the first transistor 131, and the second pixel electrode 134 and the second storage capacitor 136 are electrically connected with the second transistor 132. In addition, the second source S2 is further electrically connected with the first pixel electrode 133, so the first pixel electrode 133 and the second pixel electrode 134 are electrically connected with each other by the second transistor 132.

The first drain D1 is electrically connected with the first storage capacitor 135, the first pixel electrode 133, and the second drain D2, the second drain D2 is electrically connected with the second storage capacitor 136 and the second pixel electrode 134, and the first transistor 131 and the second transistor 132 use the same gate input signal and source input signal, so the source input signal from the data line 120d can be sent to the first pixel electrode 133 and the second pixel electrode 134, and the source input signal charge liquid crystal capacitors Clc1 and Clc2, the first storage capacitor 135, and the second storage capacitor 136.

These common lines 120c are electrically connected with the first storage capacitors 135 and second storage capacitors 136, and the first storage capacitors 135 and the second storage capacitors 136 are built on the common lines 120c (cst on common). Each pixel unit 130 can be electrically connected with two common lines 120c. One common line 120c is electrically connected with the first storage capacitor 135, and the other common line 120c is electrically connected with the second storage capacitor 136. In this way, the common lines 120c can transmit a common electrode signal Vc1 to the liquid crystal capacitors Clc1 and Clc2, the first storage capacitor 135, and the second storage capacitor 136. In addition, one scan line 120s is located between two adjacent common lines 120c.

During the operation procedure of the liquid crystal display panel 10, when a gate input signal from the scan line 120s switches on the first transistor 131 and the second transistor 132, the source input signal from the data line 120d is sent to the first pixel electrode 133 and the second pixel electrode 134 and charges the liquid crystal capacitors Clc1 and Clc2, the first storage capacitor 135, and the second storage capacitor 136. When a gate input signal from the scan line 120s switches off the first transistor 131 and the second transistor 132, the liquid crystal capacitors Clc1 and Clc2 generate different feed-through voltages respectively by the voltage division rule of capacitors

Specifically, in a conventional liquid crystal display technology, the feed-through voltage satisfies the following Formula (1):

ΔVp=(Vgh−Vgl)×[Cgd/(Cgd+Clc+Cs)] (1)

where [symbol] Vp is the feed-through voltage, Cgd is the capacitance between a gate and a drain of a transistor in a pixel unit, Clc is the capacitance of a liquid crystal capacitor, and Cs is the capacitance of a storage capacitor. Vgh and Vgl represent a high voltage and a low voltage of a gate input signal respectively. Vgh is a voltage value obtained when the gate input signal switches on the transistor, while Vgl is a voltage value obtained when the gate input signal switches off the transistor.

As seen from FIG. 1B, the capacitors connected with the scan line 120s are respectively a capacitor between the first gate G1 and the first drain D1 in the first transistor 131, and a capacitor between the second gate G2 and the second source S2 in the second transistor 132 for the first pixel electrode 133 singly. Therefore, according to Formula (1), the feed-through voltage [symbol] Vp1 generated by the liquid crystal capacitor Clc1 satisfies the following Formula (2):

ΔVp1=(Vgh−Vgl)×[(Cgd1+Cgs2)/(Cgd1+Cgs2+Clc1+Cs1)] (2)

where Cgd1 is the capacitance between the first gate G1 and the first drain D1 in the first transistor 131, Cgs2 is the capacitance between the second gate G2 and the second source S2 in the second transistor 132, Clc1 is the capacitance of the liquid crystal capacitor Clc1, and Cs1 is the capacitance of the first storage capacitor 135. Vgh is a voltage value obtained when the gate input signal switches on the first transistor 131 and the second transistor 132, while Vgl is a voltage value obtained when the gate input signal switches off the first transistor 131 and the second transistor 132. As seen from Formula (2), it can be found that Cgd in the original Formula (1) is replaced by (Cgd1+Cgs2).

Likewise, since a capacitor connected with the scan line 120s is only a capacitor between the second gate G2 and the second drain D2 in the second transistor 132 for the second pixel electrode 134 singly, so the feed-through voltage [symbol] Vp2 generated by the liquid crystal capacitor Clc2 satisfies the following Formula (3) according to Formula (1):

ΔVp2=(Vgh−Vgl)×[(Cgd2)/(Cgd2+Clc2+Cs2)] (3)

where Cgd2 is the capacitance between the second gate G2 and the second drain D2 in the second transistor 132, Clc2 is the capacitance of the liquid crystal capacitor Clc2, and Cs2 is the capacitance of the second storage capacitor 136. As seen from Formula (3), it can be found that Cgd in the original Formula (1) is replaced by Cgd2.

It is known from Formula (2) and Formula (3) that the liquid crystal capacitors Clc1 and Clc2 can generate different feed-through voltages [symbol] Vp1 and [symbol] Vp2 respectively by adjusting the capacitance between the first gate G1 and the first drain D1, the capacitance between the second gate G2 and the second source S2, the capacitance between the second gate G2 and the second drain D2, the capacitance of the first storage capacitor 135, the capacitance of the second storage capacitor 136, and the capacitance of the liquid crystal capacitors Clc1 and Clc2. In this way, each pixel unit 130 can show two different gray levels, so as to solve the color shift problem.

For the method utilizing the capacitance to generate the different feed-through voltages [symbol] Vp1 and [symbol] Vp2, the present invention has various implementations. For example, the first embodiment controls the feed-through voltages [symbol] Vp1 and [symbol] Vp2 by adjusting the capacitance between the first gate G1 and the first drain D1, the capacitance between the second gate G2 and the second source S2, and the capacitance between the second gate G2 and the second drain D2.

Referring to FIG. 1A, a channel width length ratio of each first transistor 131 differs from a channel width length ratio of each second transistor 132. The channel width length ratio is a ratio of a channel width to a channel length. For example, as seen from FIG. 1A, a channel length of the first transistor 131 is substantially the same as a channel length of the second transistor 132, but a channel width of the first transistor 131 is larger than channel width of the second transistor 132, so the channel width length ratio of each first transistor 131 is larger than the channel width length ratio of each second transistor 132. Therefore, both the capacitance between the second gate G2 and the second drain D2, and the capacitance between the second gate G2 and the second source S2 are all smaller than the value of the capacitance between the first gate G1 and the first drain D1.

According to Formula (2) and Formula (3), on the premise that the capacitances of the liquid crystal capacitors Clc1 and Clc2 are the same, and the capacitances of the first storage capacitor 135 and the second storage capacitor 136 are the same, the feed-through voltage [symbol] Vp1 is larger than the feed-through voltage [symbol] Vp2. In this way, the pixel unit 130 can show two different gray levels, so as to eliminate the color shift.

Additionally, it is noted that the channel width length ratio of the first transistor 131 is larger than that of the second transistor 132 in the first embodiment, but in other embodiment, the pixel unit 130 still can show two different gray levels even if the channel width length ratio of the first transistor 131 is smaller than that of the second transistor 132, so as to achieve the efficacy of eliminating the color shift. Therefore, the first transistor 131 and the second transistor 132 as shown in FIG. 1A are only exemplary and are intended to limit the present invention.

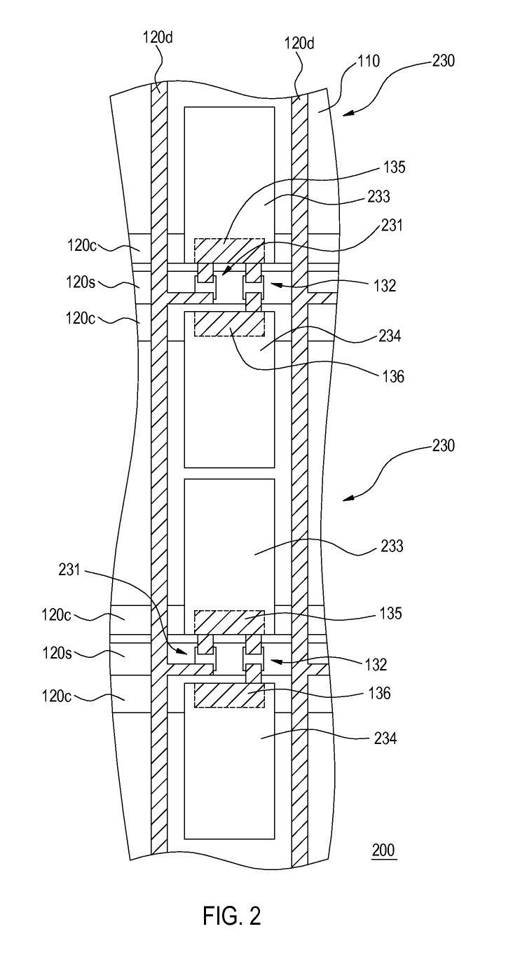

Besides adjusting the channel width length ratios of the first transistor 131 and the second transistor 132, the present invention also can control the feed-through voltages [symbol] Vp1 and [symbol] Vp2 by adjusting the capacitances of the liquid crystal capacitors Clc1 and Clc2. FIG. 2 is a schematic top view of a transistor array substrate according to a second embodiment of the present invention. Specifically, referring to FIG. 2, a transistor array substrate 200 of the second embodiment is similar to the transistor array substrate 100 of the first embodiment. For example, the transistor array substrate 200 also can form a liquid crystal display panel (not shown) through assembly with a color filter substrate (not shown) and filling of a liquid crystal material. Therefore, the same parts between the first embodiment and the second embodiment are not described again here, and only differences between the both are introduced hereinafter.

In the second embodiment, an area of each first pixel electrode 233 differs from an area of each second pixel electrode 234. Specifically, as seen from FIG. 2, it can be known that the area of each first pixel electrode 233 is smaller than the area of each second pixel electrode 234. After a liquid crystal display panel with the transistor array substrate 200 is formed, because the area of the first pixel electrode 233 is smaller than the area of the second pixel electrode 234, a liquid crystal capacitor corresponding to the first pixel electrode 233 is also smaller than a liquid crystal capacitor corresponding to the second pixel electrode 234.

In FIG. 2, capacitances of the first storage capacitor 135 and the second storage capacitor 136 are the same, and a first transistor 231 is similar to the first transistor 131 of the first embodiment. However, the channel width length ratios of the first transistor 231 and the second transistor 132 are the same, so a feed-through voltage of the first pixel electrode 233 is larger than a feed-through voltage of the second pixel electrode 234 according to Formula (2) and Formula (3) and based on the fact that the liquid crystal capacitor corresponding to the first pixel electrode 233 is smaller than the liquid crystal capacitor corresponding to the second pixel electrode 234. In this way, each pixel unit 230 of the transistor array substrate 200 can also show two different gray levels, thereby achieving the efficacy of eliminating the color shift.

Additionally, it is noted that the area of the first pixel electrode 233 is smaller than the area of the second pixel electrode 234 in the second embodiment, but in other embodiment, the pixel unit 230 still can show two different gray levels even if the area of the first pixel electrode 233 is larger than the area of the second pixel electrode 234. Therefore, the areas of the first pixel electrode 233 and the second pixel electrode 234 as shown in FIG. 2 are only exemplary and not intended to limit the present invention.

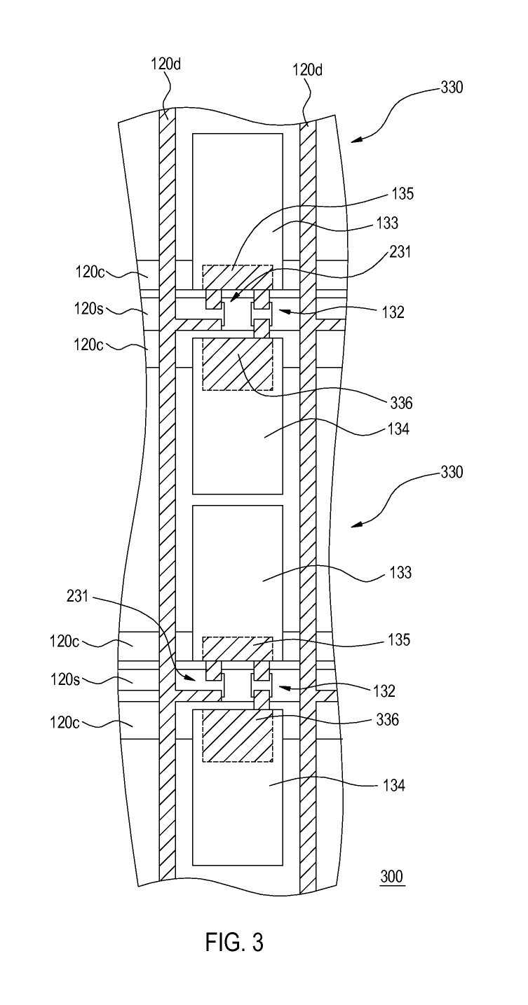

Besides controlling the feed-through voltages [symbol] Vp1 and [symbol] Vp2 described in the first and second embodiments, the present invention can also control the feed-through voltages [symbol] Vp1 and [symbol] Vp2 by adjusting capacitances Cs1 and Cs2 of the first storage capacitor and the second storage capacitor. Specifically, FIG. 3 is a schematic top view of a transistor array substrate according to a third embodiment of the present invention. Referring to FIG. 3, a transistor array substrate 300 of the third embodiment is similar to the transistor array substrates 100 and 200 of the aforementioned embodiments, so the transistor array substrate 300 can also form a liquid crystal display panel (not shown) through assembly with a color filter substrate (not shown) and filling of a liquid crystal material. Therefore, the same parts between the third embodiment and the aforementioned embodiments are not described again here, and only differences between the third embodiment and the aforementioned embodiments are introduced hereinafter.

In the third embodiment, the capacitance of each first storage capacitor 135 differs from the capacitance of each second storage capacitor 336. Specifically, as seen from FIG. 3, it can be known that an area occupied by each first storage capacitor 135 on the substrate 110 is smaller than an area occupied by each second storage capacitor 336 on the substrate 110, so that the capacitance of each first storage capacitor 135 is smaller than the capacitance of each second storage capacitor 336.

According to Formula (2) and Formula (3), on the premise that areas of the first pixel electrode 133 and the second pixel electrode 134 are the same, and channel width length ratios of the first transistor 231 and the second transistor 132 are the same in FIG. 3, a feed-through voltage of the first pixel electrode 133 is larger than a feed-through voltage of the second pixel electrode 134. In this way, each pixel unit 330 of the transistor array substrate 300 can also show two different gray levels, thereby eliminating the color shift.

Additionally, it is noted that the capacitance of the first storage capacitor 135 is smaller than the capacitance of the second storage capacitor 336 in the third embodiment, but in other embodiment, the pixel unit 330 still can present two different gray levels even if the capacitance of the first storage capacitor 135 is larger than the capacitance of the second storage capacitor 336. Therefore, the first storage capacitor 135 and the second storage capacitor 336 as shown in FIG. 3 are only exemplary and not intended to limit the present invention.

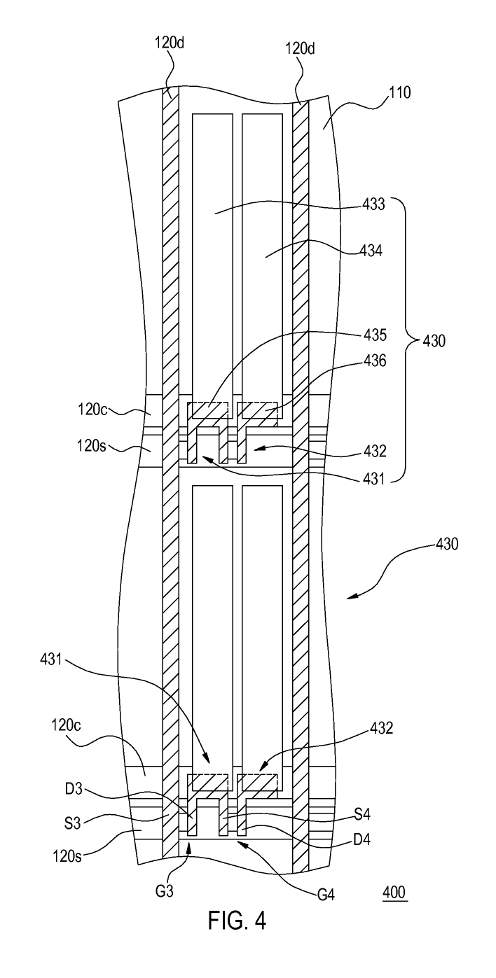

FIG. 4 is a schematic top view of a transistor array substrate according to a fourth embodiment of the present invention. Referring to FIG. 4, a transistor array substrate 400 of the fourth embodiment is similar to the transistor array substrate 100 of the first embodiment, and circuit structures of the both are the same. Specifically, the transistor array substrate 400 includes a substrate 110, a plurality of scan lines 120s, a plurality of data lines 120d, a plurality of common lines 120c, and a plurality of pixel units 430. Each pixel unit 430 includes a first transistor 431, a second transistor 432, a first pixel electrode 433, a second pixel electrode 434, a first storage capacitor 435, and a second storage capacitor 436. The scan lines 120s, the data lines 120d, the common lines 120c, and the pixel units 430 are all disposed on the substrate 110.

The first transistor 431 and the second transistor 432 are all field-effect transistors, so each first transistor 431 includes a first gate G3, a first source S3, and a first drain D3, and each second transistor 432 includes a second gate G4, a second source S4, and a second drain D4. A pixel unit 430 is electrically connected with a scan line 120s and a data line 120d, and the electrical connection among the three is the same as that in the first embodiment.

Specifically, in each pixel unit 430, the first gate G3 and the second gate G4 are electrically connected with the same scan line 120s, and the first source S3 is electrically connected with the data line 120d. The first drain D3 is electrically connected with the second source S4, the first storage capacitor 435, and the first pixel electrode 433, and the second drain D4 is electrically connected with the second storage capacitor 436 and the second pixel electrode 434. In addition, the implementation for the transistor array substrate 400 eliminating the color shift is the same as that in the aforementioned embodiments, and it will not describe how transistor array substrate 400 eliminates the color shift again here.

However, a difference still exists between the transistor array substrates 400, 100 and lies in that: both arrangements of the pixel units are different. Specifically, in the fourth embodiment, the first pixel electrode 433 and the second pixel electrode 434 in each pixel unit 430 are arranged into one row along the data line 120d. It is different from the longitudinal arrangement presented by the first pixel electrode 133 and the second pixel electrode 134 in the first embodiment, and the first pixel electrode 433 and the second pixel electrode 434 of this embodiment are in a transverse arrangement. Additionally, in the same pixel unit 430, the first storage capacitor 435 and the second storage capacitor 436 are electrically connected with the same common line 120c, as shown in FIG. 4.

In view of the foregoing, the present invention can generate different feed-through voltages at the first pixel electrode and the second pixel electrode respectively by utilizing the voltage division rule of capacitors and adjusting the capacitance between the first gate and the first drain, the capacitance between the second gate and the second source, the capacitance between the second gate and the second drain, the capacitance of the first storage capacitor, the capacitance of the second storage capacitor, and the capacitances of the liquid crystal capacitors corresponding to the first pixel electrode and the second pixel electrode respectively. In this way, each pixel unit can show two different gray levels, thereby solving the color shift problem.

Compared with the prior art, the present invention is not easily influenced by manufacturing process parameters and therefore has preferred voltage accuracy, thereby controlling the electric fields of the pixel electrodes precisely to avoid the negative influence on the picture quality of the liquid crystal display. Besides, in the present invention, two transistors (that is, first and second transistors) are adopted in a single pixel unit, but it is not necessary like the prior art to add a plurality of extra scan lines and to input the signals with independent waveforms, so a customized driver IC is not required. It can be known from this that the transistor array substrate of the present invention has advantages of a simple fabrication procedure and reduced fabrication cost.

Furthermore, the transistor array substrate of the present invention in general can be manufactured with an existing liquid crystal display panel manufacturing process, and the transistor array substrate manufacturing process of the present invention is similar to the current manufacturing process of transistor array substrates, so in manufacturing, the transistor array substrate of the present invention does not need to greatly change the manufacturing equipment and the manufacturing process of existing transistor array substrates. In this way, the transistor array substrate of the present invention can be manufactured by using the existing manufacturing device and manufacturing process, thereby saving expenses for additional equipment purchase.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed is:

1. A transistor array substrate, comprising:
a substrate;
a plurality of scan lines, disposed on the substrate;
a plurality of data lines, disposed on the substrate; and
a plurality of pixel units, disposed on the substrate, wherein each of the pixel units comprises:
a first transistor;
a second transistor, wherein the second transistor and the first transistor are electrically connected with the same scan line and the same data line, and the second transistor and the first transistor are connected in series;
a first pixel electrode, electrically connected with the first transistor;
a second pixel electrode, electrically connected with the second transistor;
a first storage capacitor, electrically connected with the first transistor and the second transistor; and
a second storage capacitor, electrically connected with the second transistor.

2. The transistor array substrate according to claim 1, wherein each of the first transistors comprises a first gate, a first source, and a first drain, and each of the second transistors comprises a second gate, a second source, and a second drain; in each of the pixel units, the first gate and the second gate are electrically connected with the same scan line, the first source is electrically connected with the data line, the first drain is electrically connected with the second source, the first storage capacitor, and the first pixel electrode, and the second drain is electrically connected with the second storage capacitor and the second pixel electrode.

3. The transistor array substrate according to claim 1, further comprising a plurality of common lines, wherein the common lines are electrically connected with the first storage capacitors and the second storage capacitors, and the first storage capacitors and the second storage capacitors are built on the common lines.

4. The transistor array substrate according to claim 3, wherein one scan line is located between two adjacent common lines, one of the two adjacent common lines is electrically connected with the first storage capacitor, and the other common line is electrically connected with the second storage capacitor.

5. The transistor array substrate according to claim 3, wherein the first storage capacitor and the second storage capacitor in the same pixel unit are electrically connected with the same common line.

6. The transistor array substrate according to claim 1, wherein the first pixel electrode and the second pixel electrode in each of the pixel units are arranged into one row along the data line.

7. The transistor array substrate according to claim 1, wherein the first pixel electrode and the second pixel electrode in each of the pixel units are arranged into one row along the scan line.

8. The transistor array substrate according to claim 1, wherein a channel width length ratio of each of the first transistors differs from a channel width length ratio of each of the second transistors.

9. The transistor array substrate according to claim 8, wherein the channel width length ratio of each of the first transistors is larger than the channel width length ratio of each of the second transistors.

10. The transistor array substrate according to claim 1, wherein an area of each of the first pixel electrodes differs from an area of each of the second pixel electrodes.

11. The transistor array substrate according to claim 10, wherein the area of each of the first pixel electrodes is smaller than the area of each of the second pixel electrodes.

12. The transistor array substrate according to claim 1, wherein a capacitance of each of the first storage capacitors differs from a capacitance of each of the second storage capacitors.

13. The transistor array substrate according to claim 12, wherein the capacitance of each of the first storage capacitors is smaller than the capacitance of each of the second storage capacitors.
